(19) United States
(12) Patent Application Publication
(10) Pub. No.: US 2024/0241230 A1
(43) Pub. Date: Jul. 18, 2024

(54) PHOTOELECTRIC CONVERSION DEVICE

(71) Applicant: CANON KABUSHIKI KAISHA, Tokyo (JP)

(72) Inventors: KAZUNORI MATSUYAMA, Kanagawa (JP); NORIYUKI SHIKINA, Tokyo (JP)

(21) Appl. No.: 18/411,483

(22) Filed: Jan. 12, 2024

(30) Foreign Application Priority Data
Jan. 18, 2023 (JP) 2023-005962

(51) Int. Cl. G01S 7/4863; G01S 17/10; G01S 17/894; H01L 31/107; G01S 17/931

(52) U.S. Cl. CPC G01S 7/4863; G01S 17/10; G01S 17/894; H01L 31/107; G01S 17/931

(57) ABSTRACT

A photoelectric conversion device including: a light receiving unit including pixels each generates a signal based on incident light; and a frequency distribution generation unit generating a frequency distribution in which time information on a time from light emission of a light emitting device to light reception of the light receiving unit is associated with a frequency of light reception by accumulating light reception results at the light receiving unit a plurality of times. The frequency distribution generation unit operates in either a first mode for generating the frequency distribution from the light reception results of one of the pixels, or a second mode for generating the frequency distribution in which the light reception results of multiple pixels are accumulated. A second accumulation number of the light reception results in the second mode is less than a first accumulation number of the light reception results in the first mode.

### BACKGROUND OF THE INVENTION

### Field of the Invention

The present invention relates to a photoelectric conversion device.

### Description of the Related Art

Japanese Patent Application Laid-Open No. 2020-091117 and Japanese Patent Application Laid-Open No. 2021-103101 disclose a ranging device that measures a distance to an object by emitting light from a light emitting unit and receiving light including reflected light from the object by a light receiving unit having a plurality of pixels. These ranging devices have a function of integrating outputs of the plurality of pixels. Japanese Patent Application Laid-Open No. 2020-091117 and Japanese Patent Application Laid-Open No. 2021-103101 disclose a method of changing spatial resolution by switching a range in which outputs are integrated.

In a photoelectric conversion device having a function of switching spatial resolution as disclosed in Japanese Patent Application Laid-Open No. 2020-091117 and Japanese Patent Application Laid-Open No. 2021-103101, further improvement of a frame rate may be required.

### SUMMARY OF THE INVENTION

According to a disclosure of the present specification, there is provided a photoelectric conversion device including: a light receiving unit including a plurality of pixels each configured to generate a signal based on incident light; and a frequency distribution generation unit configured to generate a frequency distribution in which time information on a time from light emission of a light emitting device to light reception of the light receiving unit is associated with a frequency of light reception by accumulating light reception results at the light receiving unit a plurality of times. The frequency distribution generation unit operates in either a first mode for generating the frequency distribution from the light reception results of one of the plurality of pixels, or a second mode for generating the frequency distribution in which the light reception results of multiple pixels among the plurality of pixels are accumulated. A second accumulation number of the light reception results in the second mode is less than a first accumulation number of the light reception results in the first mode.

Further features of the present invention will become apparent from the following description of exemplary embodiments with reference to the attached drawings.

### BRIEF DESCRIPTION OF THE DRAWINGS

FIG. 1 is a hardware block diagram illustrating a schematic configuration example of a ranging device according to a first embodiment.

FIG. 2 is a functional block diagram illustrating a schematic configuration example of the ranging device according to the first embodiment.

FIGS. 3A and 3B are block diagrams schematically illustrating binning processing according to the first embodiment.

FIG. 4 is a diagram illustrating an outline of ranging frame acquisition according to the first embodiment.

FIG. 5 is a flowchart illustrating an operation of the ranging device according to the first embodiment.

FIG. 6 is a diagram illustrating an outline of ranging frame acquisition according to a second embodiment.

FIG. 7 is a flowchart illustrating an operation of the ranging device according to the second embodiment.

FIGS. 8A, 8B, and 8C are schematic views illustrating an outline of an operation of the ranging device according to a third embodiment.

FIG. 9 is a functional block diagram illustrating a schematic configuration example of the ranging device according to a fourth embodiment.

FIGS. 10A and 10B are block diagrams schematically illustrating binning processing according to the fourth embodiment.

FIG. 11 is a schematic view illustrating an overall configuration of the photoelectric conversion device according to a fifth embodiment.

FIG. 12 is a schematic block diagram illustrating a configuration example of a sensor substrate according to the fifth embodiment.

FIG. 13 is a schematic block diagram illustrating a configuration example of a circuit substrate according to the fifth embodiment.

FIG. 14 is a schematic block diagram illustrating a configuration example of one pixel of a photoelectric conversion unit and a pixel signal processing unit according to the fifth embodiment.

FIGS. 15A, 15B, and 15C are diagrams illustrating an operation of an avalanche photodiode according to the fifth embodiment.

FIGS. 16A and 16B are schematic diagrams of equipment according to a sixth embodiment.

### DESCRIPTION OF THE EMBODIMENTS

Embodiments of the present invention will now be described with reference to the accompanying drawings. In the drawings, the same or corresponding elements are denoted by the same reference numerals, and the description thereof may be omitted or simplified. The following embodiments do not limit the present invention, and matters described in the following embodiments may include matters which are not essential to the present invention.

### First Embodiment

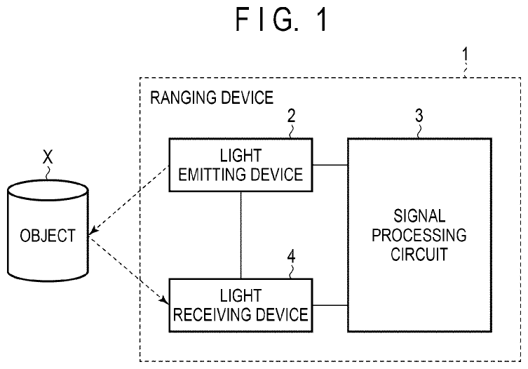

FIG. 1 is a hardware block diagram illustrating a schematic configuration example of a ranging device 1 according to the present embodiment. The ranging device 1 includes a light emitting device 2, a signal processing circuit 3, and a light receiving device 4. Note that the configuration of the ranging device 1 illustrated in the present embodiment is an example, and is not limited to the illustrated configuration.

The ranging device 1 measures a distance to an object X by using a technology such as a light detection and ranging (LiDAR). The ranging device 1 measures the distance from the ranging device 1 to the object X based on a time difference until the light emitted from the light emitting device 2 and reflected by the object X is received by the light receiving device 4. Further, the ranging device 1 can measure the distance at a plurality of points in a two-dimensional manner by emitting laser light to a predetermined ranging area including the object X and receiving reflected light by the pixel array. Thus, the ranging device 1 can generate and output a distance image. Such a scheme is sometimes referred to as a flash LiDAR.

The light received by the light receiving device 4 includes ambient light such as sunlight in addition to the reflected light from the object X. Therefore, the ranging device 1 generates a frequency distribution in which incident light is counted in each of a plurality of periods (bin periods) and determines that reflected light is incident in a period in which the light amount peaks, thereby performing ranging in which the influence of ambient light is reduced.

The light emitting device 2 is a device that emits light such as laser light to the outside of the ranging device 1. The signal processing circuit 3 may include a processor that performs arithmetic processing of digital signals, a memory that stores digital signals, and the like. The memory may be, for example, a semiconductor memory.

The light receiving device 4 generates a pulse signal including a pulse based on the incident light. The light receiving device 4 is, for example, a photoelectric conversion device including an avalanche photodiode as a photoelectric conversion element. In this case, when one photon is incident on the avalanche photodiode and a charge is generated, one pulse is generated by avalanche multiplication. However, the light receiving device 4 may include, for example, a photoelectric conversion element using another photodiode.

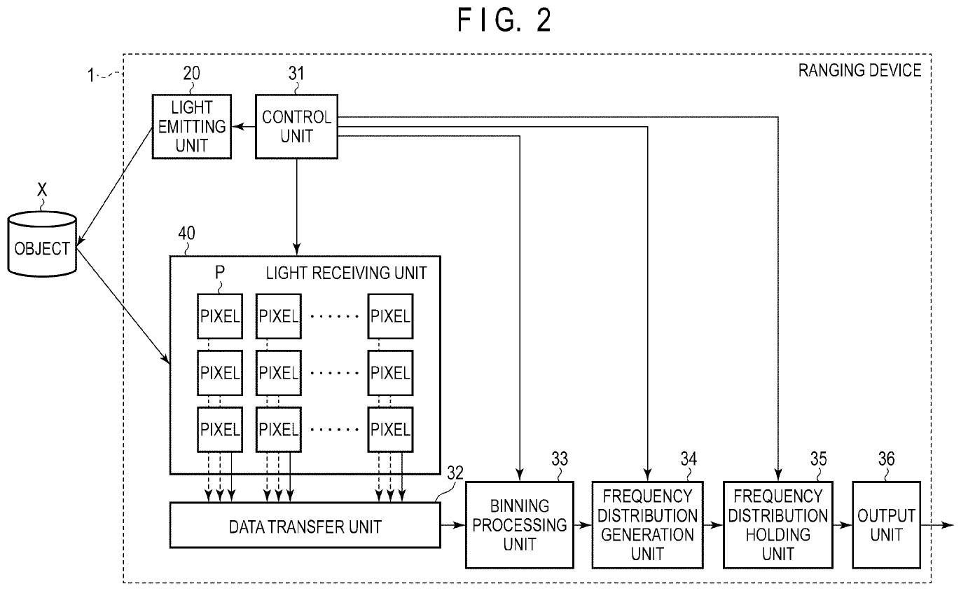

FIG. 2 is a functional block diagram illustrating a schematic configuration example of the ranging device 1 according to the present embodiment. The ranging device 1 includes a light emitting unit 20, a light receiving unit 40, a control unit 31, a data transfer unit 32, a binning processing unit 33, a frequency distribution generation unit 34, a frequency distribution holding unit 35, and an output unit 36.

The light receiving unit 40 includes a plurality of pixels P arranged to form a plurality of rows and a plurality of columns. Each of the plurality of pixels P includes a photoelectric conversion element and a pixel circuit for reading out a signal from the photoelectric conversion element. In the following description, the photoelectric conversion element is assumed to be an avalanche photodiode.

The light receiving unit 40 and the light emitting unit 20 correspond to the light receiving device 4 and the light emitting device 2 in FIG. 1, respectively. The control unit 31, the data transfer unit 32, the binning processing unit 33, the frequency distribution generation unit 34, the frequency distribution holding unit 35, and the output unit 36 correspond to the signal processing circuit 3 in FIG. 1.

The control unit 31 outputs a light emission control signal for controlling a timing of light emission to the light emitting unit 20. Further, the control unit 31 outputs an exposure control signal corresponding to a ranging distance and a scanning signal of the pixel P to the light receiving unit 40. Further, the control unit 31 outputs a control signal for controlling the operations of the binning processing unit 33, the frequency distribution generation unit 34, and the frequency distribution holding unit 35. The control signal has, for example, a function of notifying an operation mode and distance information and a function of controlling timings of the start and the end of a frame.

The photoelectric conversion element of the pixel P converts light into an electric signal when a photon is detected during a period in which the exposure control signal output from the control unit 31 is enabled. The pixel circuit of the pixel P outputs the electric signal converted by the photoelectric conversion unit to a pixel output signal line. The light receiving unit 40 includes a vertical scanning circuit (not illustrated) that receives a control pulse supplied from the control unit 31 and supplies a control pulse to each pixel P. A logic circuit such as a shift register or an address decoder may be used for the vertical scanning circuit. A signal output from the photoelectric conversion unit of each pixel P is processed in the pixel circuit of the pixel P. A memory is provided in the pixel circuit, and the memory holds a digital signal (data) indicating whether or not light is received by the pixel P.

The control unit 31 outputs a control pulse for sequentially selecting a read region to the light receiving unit 40. As a result, a digital signal is read from the memory of the pixel P in the selected read region to the data transfer unit 32 via a vertical signal line. In the present embodiment, digital signals are output in parallel from the pixels P of two rows.

Although a plurality of pixels P are two-dimensionally arranged in the light receiving unit 40, a plurality of pixels P may be one-dimensionally arranged. Further, the function of the pixel circuit is not necessarily one for all the pixels P. For example, one pixel circuit may be shared by a plurality of pixels P. In this case, the pixel circuit sequentially processes signals from a plurality of pixels P. The ranging device 1 may have a structure in which a first substrate having the photoelectric conversion element and a second substrate having the pixel circuit are stacked. Thereby, the ranging device 1 can have high sensitivity and high functionality.

The data transfer unit 32 collectively acquires data from a plurality of pixels P of the light receiving unit 40 at a predetermined timing. Then, the data transfer unit 32 outputs the data acquired from the plurality of pixels P at a constant clock cycle until the next data input. The data transfer unit 32 outputs data according to the number of output data per clock corresponding to the number of parallel processes in the binning processing unit 33 and the frequency distribution generation unit 34 in the subsequent stage. In the present embodiment, two rows of data per clock are input in parallel to the binning processing unit 33 and the frequency distribution generation unit 34. That is, the data transfer unit 32 outputs the inputted data as it is. One unit of data thus read out from the light receiving unit 40 is referred to as a micro-frame.

The frequency distribution generation unit 34 accumulates data indicating the light reception result output from the binning processing unit 33 a plurality of times for each distance based on measurement distance information input from the control unit 31. Here, the measurement distance information includes information indicating a setting of a distance at which measurement is performed by the light receiving unit 40 at the present time. Since the measurement distance is proportional to the flight time of the light, the measurement distance information can be referred to as time information from the light emission in the light emitting unit 20 to the light reception in the light receiving unit 40. In the present embodiment, measurements of a plurality of micro-frames are performed for each distance. Then, a plurality of distances are measured while changing the time from the light emission to the enabling of the exposure control signal. The frequency distribution generation unit 34 accumulates the micro-frames for each class corresponding to the distance, thereby generating a frequency distribution in which the distance is defined as the class, the number of times of light reception is defined as the frequency, and the class and the frequency are associated with each other.

The frequency distribution holding unit 35 has a memory for holding the frequency distribution generated by the frequency distribution generation unit 34. The output unit 36 is an interface that outputs information to the outside of the ranging device 1 in a predetermined format. The information held in the frequency distribution holding unit 35 may be output to an external signal processing device via the output unit 36 as it is. Alternatively, the frequency distribution holding unit 35 may perform peak detection processing for detecting a peak from the frequency distribution to generate distance information and output the distance information to an external signal processing device.

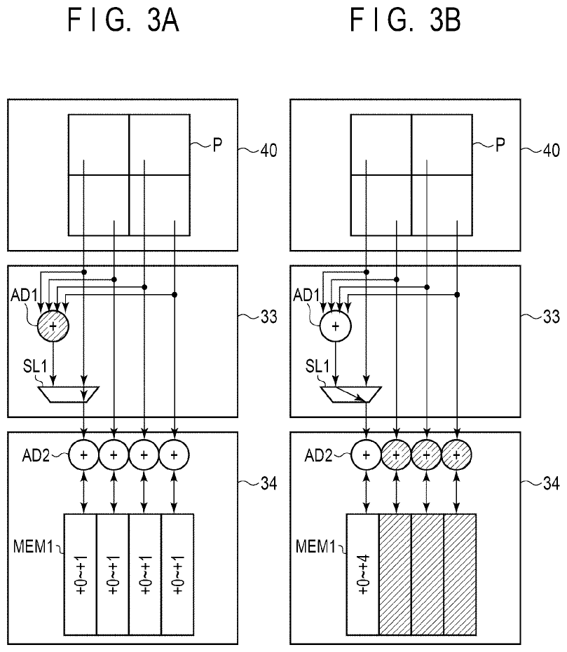

FIGS. 3A and 3B are block diagrams schematically illustrating binning processing according to the present embodiment. FIGS. 3A and 3B illustrate elements related to the binning processing in the light receiving unit 40, the binning processing unit 33, and the frequency distribution generation unit 34 in more detail. The frequency distribution generation unit 34 can operate in either a state in which the binning processing is disabled (first mode) or a state in which the binning processing is enabled (second mode) according to a control signal from the control unit 31. FIG. 3A illustrates an operation when the binning processing is disabled, and FIG. 3B illustrates an operation when the binning processing is enabled. As illustrated in FIGS. 3A and 3B, in the binning processing in the present embodiment, the binning processing is performed on four pixels P in two rows adjacent to each other and two columns adjacent to each other, but the number of pixels P subject to the binning processing is not limited thereto and is only required to be plural.

As illustrated in FIGS. 3A and 3B, the binning processing unit 33 includes an adder AD1 and a selection circuit SL1. The frequency distribution generation unit 34 includes four adders AD2 corresponding to four pixels P and four memories MEM1 corresponding to four pixels. In FIGS. 3A and 3B, hatched elements indicate elements that do not operate.

The output signals from the four pixels P are input to the adder AD1. The adder AD1 has a function of adding these input signals and outputting the added signal to the selection circuit SL1. The selection circuit SL1 receives an output signal of the adder AD1 and an output signal from one of the four pixels P. The selection circuit SL1 outputs one of these signals in response to a control signal from the control unit 31.

The output signal of the selection circuit SL1 is input to one of the four adders AD2, and the output signals of the three pixels P are input to the other three adders AD2, respectively. The adder AD2 has a function of adding the value of the input signal to the data stored in the corresponding memory MEM1 and writing it back to the corresponding memory MEM1.

As illustrated in FIG. 3A, when the binning processing is disabled, the selection circuit SL1 outputs a signal from one pixel P in response to the control signal from the control unit 31. Thus, the output signal of each pixel P is input to the corresponding adder AD2 without binning processing. Each adder AD2 adds zero or one to the value of the data held in the corresponding memory MEM1 according to the output signal of corresponding pixel P. That is, when the binning processing is disabled, the frequency distribution generation unit 34 adds the frequency by one at the maximum every time the reading is performed once. In this processing, the adder AD1 is not used.

As illustrated in FIG. 3B, when the binning processing is enabled, the selection circuit SL1 outputs a signal obtained by adding the signals from the four pixels P by the adder AD1 in response to the control signal from the control unit 31. The adder AD2 to which this signal is input adds zero to four to the value of the data held in the memory MEM1 according to the sum of the output signals of the pixels P. In this case, the three adders AD2 are not used by the binning processing, and the number of output signals becomes ¼. When the binning processing is enabled, the frequency distribution generation unit 34 adds the frequency by four at the maximum every time the reading is performed once. Further, the spatial resolution of the acquired signal becomes ½ in both the row direction and the column direction. For a storage area of the memories MEM1 which is not used at the time of binning processing, it is preferable to perform power saving processing by a method such as stopping or reducing the supply of power. Thereby, the power consumption of the memories MEM1 when the binning processing is enabled can be made smaller than the power consumption of the memories MEM1 when the binning processing is disabled.

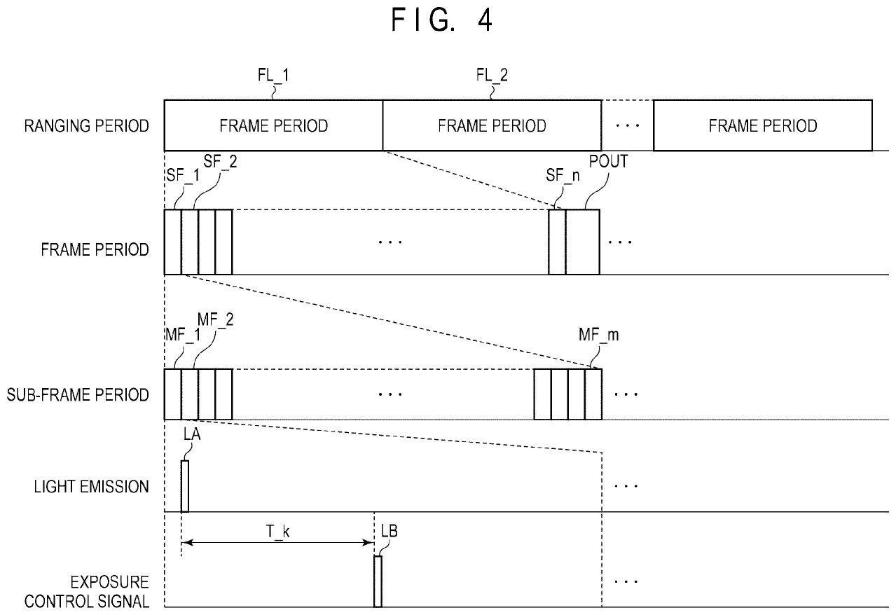

FIG. 4 is a diagram illustrating an outline of ranging frame acquisition according to the present embodiment. FIG. 4 schematically illustrates acquisition periods of a ranging frame corresponding to one ranging result, a sub-frame used for generation of the ranging frame, and a micro-frame used for generation of the sub-frame by arranging blocks in the horizontal direction. The horizontal direction in FIG. 4 indicates the elapse of time, and one block indicates the acquisition period of one ranging frame, one sub-frame, or one micro-frame. In addition, FIG. 4 illustrates a control signal for controlling the light emission period of the light emitting unit 20 and an exposure control signal for controlling the light receiving period of the light receiving unit 40. In FIG. 4, it is assumed that the binning processing is disabled.

In the “ranging period” of FIG. 4, a plurality of frame periods FL1, FL2, . . . included in one ranging period are illustrated. The frame period FL1 indicates the first frame period in one ranging period, and the frame period FL2 indicates the second frame period in one ranging period. The frame period is a period in which the ranging device 1 performs one ranging and outputs a signal indicating a distance (ranging result) from the ranging device 1 to the object X to the outside.

One ranging frame is generated from a plurality of sub-frames. In the “frame period” of FIG. 4, a plurality of sub-frame periods SF_1, SF_2, . . . , SF_n included in one frame period and a peak output period POUT for determining a peak from a frequency distribution and outputting the peak are illustrated. The sub-frame period SF_1 indicates the first sub-frame period in one frame period, and the sub-frame period SF_2 indicates the second sub-frame period in one frame period. In the present embodiment, the number of sub-frames is n per frame (n is an integer equal to or greater than two). The sub-frame period SF_n indicates the n-th sub-frame period in one frame period.

One sub-frame is generated from a plurality of micro-frames. In the “sub-frame period” of FIG. 4, a plurality of micro-frame periods MF_1, MF_2, . . . , MF_m included in one sub-frame period are illustrated. The micro-frame period MF_1 indicates the first micro-frame period in one sub-frame period, and the micro-frame period MF_2 indicates the second micro-frame period in one sub-frame period. In the present embodiment, the number of micro-frames is m per sub-frame (m is an integer equal to or greater than two). The micro-frame period MF_m indicates the m-th sub-frame period in one sub-frame period. The number m of the micro-frames corresponds to the number of accumulations of the light reception results.

In FIG. 4, “light emission” and “exposure control signal” indicate the light emission period of the light emitting unit 20 and the exposure control signal input to the light receiving unit 40 in one micro-frame period. The light emitting unit 20 emits light during the light emission period LA in which the “light emission” is at the high level. When light is incident on the pixel P of the light receiving unit 40 in the exposure period LB in which the “exposure control signal” is at the high level, the incident light is detected in the pixel P. A period T_k from the start of the light emission period LA to the start of the exposure period LB corresponds to a flight time of light from light emission to light reception. That is, the length of the period T_k corresponds to the ranging distance in the corresponding micro-frame. Note that k is a number of a corresponding sub-frame period and is an integer from 1 to n.

In each of the plurality of micro-frame periods MF_1, MF_2, . . . , MF_m, a period T_k from the start of the light emission period LA to the start of the exposure period LB is the same. That is, in one sub-frame period, the light reception data is read (micro-frame acquisition) m times. When one or more photons are detected in one micro-frame period in each pixel P, the pixel outputs “1” as light reception data. By accumulating m sub-frames acquired in one sub-frame period, data indicating the number of micro-frames in which a photon has been detected is generated.

In each of the plurality of sub-frame periods SF_1, SF_2, . . . , SF_n, the lengths of the periods T_1, T_2, . . . , T_n are different from each other. Thereby, in each of the plurality of sub-frame periods SF_1, SF_2, . . . , SF_n, frequency distributions of light reception at different distances are acquired. In the peak output period POUT, a peak (maximum value) is detected from the frequency of each of the sub-frame periods SF_1, SF_2, . . . , SF_n. The length of the period T_k corresponding to this peak is proportional to the distance from the ranging device 1 to the object X.

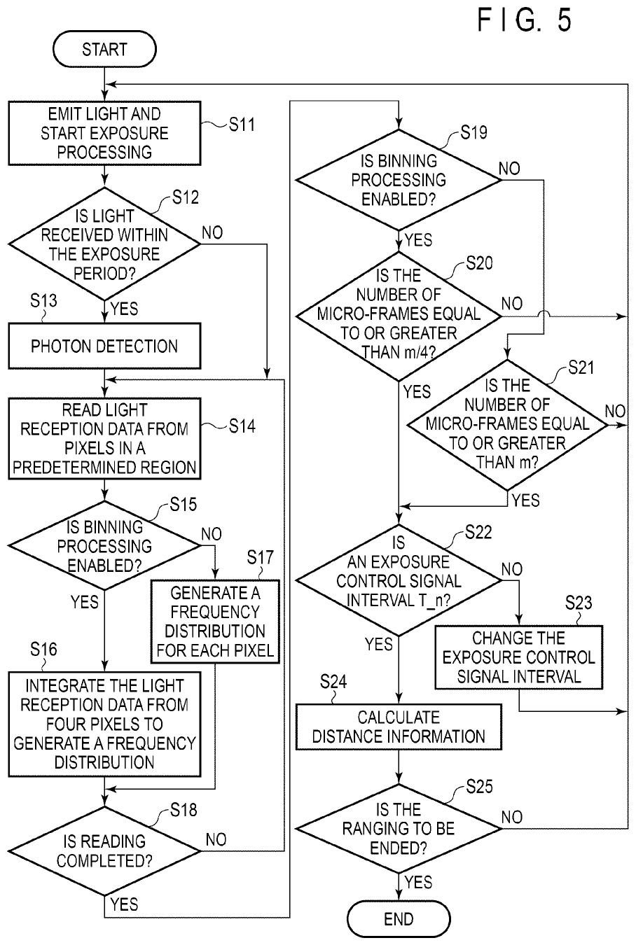

FIG. 5 is a flowchart illustrating an operation of the ranging device 1 according to the present embodiment. FIG. 5 illustrates the operation from the start to the end of the ranging period. The processing of one cycle in a loop from step S11 to step S23 represents the processing of acquiring one sub-frame in FIG. 4. The processing of one cycle in a loop from step S11 to step S20 (or step S21) represents the processing of acquiring one micro-frame in FIG. 4.

In step S11, the control unit 31 controls the light emitting unit 20 to emit pulse light within a predetermined ranging area. The control unit 31 controls the light receiving unit 40 to start exposure processing for detecting incident light. When the processing in the step S11 is the first time, the period (exposure control signal interval) corresponding to the interval between light emission and light reception is set to T_1.

In step S12, when a photon is incident on a certain pixel P within the exposure period (YES in the step S12), the process proceeds to step S13, and the pixel P generates a photon detection signal (light reception pulse) indicating detection of the photon. The photon detection signal is held as light reception data in a memory in the pixel P. For the pixels in which no photon is incident within the exposure period (NO in the step S12), the process proceeds to step S14. The processing of the step S12 and the processing of the step S13 are performed in parallel for each pixel P.

In the step S14, under the control of the reading scan by the control unit 31, the light reception data is read out from the pixels P in a predetermined region to the binning processing unit 33 via the data transfer unit 32.

In step S15, the binning processing unit 33 determines whether or not the binning processing of the light reception data is enabled based on a control signal indicating the presence or absence of binning from the control unit 31. When the binning is enabled (YES in the step S15), the process proceeds to step S16. When the binning is disabled (NO in the step S15), the process proceeds to step S17.

In the step S16, as illustrated in FIG. 3B, the binning processing unit 33 and the frequency distribution generation unit 34 perform the binning processing for integrating the light reception data from the four pixels P to generate a frequency distribution (second mode).

In the step S17, as illustrated in FIG. 3A, the binning processing unit 33 and the frequency distribution generation unit 34 do not perform the binning processing. That is, a frequency distribution is generated for each pixel P based on the light reception data from the pixel P (first mode).

In step S18, the control unit 31 determines whether or not the reading of all the pixel data of the reading target area is completed. When the reading is not completed (NO in the step S18), the process proceeds to the step S14, where reading area is changed and the reading is continued. When the reading is completed (YES in the step S18), the process proceeds to step S19.

In the step S19, the binning processing unit 33 determines whether or not the binning processing of the light reception data is enabled based on a control signal indicating the presence or absence of binning from the control unit 31. When the binning processing is enabled (YES in the step S19), the process proceeds to step S20. When the binning process is disabled (NO in the step S19), the process proceeds to step S21.

In the step S21 where the binning processing is disabled, the control unit 31 determines whether or not the number of micro-frames acquired in the sub-frame is equal to or greater than m. When the number of acquired micro-frames is less than m (NO in the step S21), the process proceeds to the step S11, and the next micro-frame is acquired. When the number of acquired micro-frames is equal to or greater than m (YES in the step S21), the process proceeds to step S22. By this processing, when the binning processing is disabled, m (first accumulation number) micro-frames are acquired and accumulated.

In the step S20 where the binning processing is enabled, the control unit 31 determines whether or not the number of micro-frames acquired in the sub-frame is equal to or greater than m/4. When the number of acquired micro-frames is less than m/4 (NO in the step S20), the process proceeds to the step S11, where the next micro-frame is acquired. When the number of acquired micro-frames is equal to or greater than m/4 (YES in the step S20), the process proceeds to the step S22. By this processing, when the binning processing is enabled, m/4 (second accumulation number) micro-frames are acquired and accumulated.

As illustrated in FIG. 3B, if the binning processing is enabled, the frequency is added by four at the maximum per micro-frame may be added. On the other hand, when the binning processing is disabled, the frequency that can be added per micro-frame is one at the maximum. Therefore, when the binning processing is enabled, the ranging result is added to the frequency distribution four times (the number of pixels to be binned) faster than when the binning processing is disabled. Therefore, when the binning processing is enabled, the threshold values of the processing of the step S20 and the processing of the step S21 are set such that the number of micro-frames per one sub-frame is ¼ (the inverse of the number of pixels to be binned) in comparison with the case where the binning processing is disabled. Thus, when the binning processing is enabled, the time required for generating the ranging frame is reduced to about ¼ in comparison with the case where the time required when the binning processing is disabled.

In step S22, the control unit 31 determines whether or not the exposure control signal interval is T_n (exposure control signal interval in the last sub-frame). When the exposure control signal interval is not T_n (NO in the step S22), the process proceeds to step S23. When the exposure control signal interval is T_n (YES in the step S22), the process proceeds to step S24.

In the step S23, the control unit 31 changes the setting value of the exposure control signal interval to a value for the next sub-frame. For example, when the exposure control signal interval is T_1, the control unit 31 changes the exposure control signal interval to T_2. Then, the process proceeds to the step S11, where the next sub-frame is acquired.

In the step S24, the frequency distribution holding unit 35 has already acquired the frequency distribution with n kinds of exposure control signal intervals from T_1 to T_n. The frequency distribution holding unit 35 or an external signal processing device performs peak detection processing for detecting a peak of the frequency distribution to generate distance information. For example, the peak detection processing may be processing of acquiring the maximum value of the frequency over a plurality of acquired classes and calculating the distance from the ranging device 1 to the object X based on the exposure control signal interval corresponding to the maximum value. More specifically, the distance Y can be calculated by Y=c×T_p/2, where the exposure control signal interval corresponding to the peak is T_p and the light speed is c (about 300,000 km/s).

In step S25, the control unit 31 determines whether or not the ranging is to be ended. When it is determined that the ranging is to be ended (YES in the step S25), the process ends. When it is determined that the ranging is not to be ended (NO in the step S25), the process proceeds to the step S11, where the next ranging frame is acquired.

As described above, according to the present embodiment, when the binning processing is enabled, the number of micro-frames to be acquired can be reduced, and the processing time can be shortened. Accordingly, a photoelectric conversion device capable of improving a frame rate is provided.

A specific example of reduction of the number of micro-frames will be described. For example, it is assumed that the maximum value of the number of photons detected per one sub-frame is 63, and the ranging processing is performed for 128 distances (128 sub-frames). In this case, the storage capacity required for holding the frequency distribution per distance and per pixel is 6 bits. In a case where the maximum value of the frequency per one distance is 63, the number of micro-frames per one sub-frame is 63 when the binning processing is disabled, and the maximum value of the frequency per one distance is 16 when the binning processing is enabled. Note that since 16×4 is 64, the number of detected photons may be 64 when the binning processing is disabled, but in this case, one frequency is discarded and 63 is held. The number of micro-frames corresponding to 128 distances when the binning processing is disabled is 63×128=8064 micro-frames. On the other hand, the number of micro-frames corresponding to 128 distances when the binning processing is enabled is 16×128=2048 micro-frames. Therefore, the number of micro-frames is generally proportional to the inverse of the number of pixels to be binned. Accordingly, the larger the number of pixels to be binned, the smaller the number of micro-frames.

In the present embodiment, the rate of change of the number of micro-frames with or without binning is fixed to 1:4, but the rate of change may be dynamically changed according to the control of the control unit 31. For example, when the reflectance of the object is low and the frequency of light reception cannot be sufficiently ensured, the probability of detection of photons can be increased by performing the binning processing. When the binning processing is performed in such an application, the number of micro-frames when the binning processing is enabled may be more than ¼ times the number of micro-frames when the binning is disabled (more than the inverse of the number of pixels to be binned). As a result, the frequency of light reception can be increased, and the accuracy of the signal can be improved. On the contrary, in a case where the reflectance of the object is high, the number of micro-frames when the binning processing is enabled may be smaller than ¼ times the number of micro-frames when the binning processing is disabled (smaller than the inverse of the number of pixels to be binned). This makes the processing faster. That is, the ratio of the number of micro-frames when the binning processing is enabled to the number of micro-frames when the binning processing is disabled may be equal to or greater than the inverse of the number of pixels to be binned, or may be less than the inverse of the number of pixels to be binned.

The frequency distribution holding unit 35 of the present embodiment is assumed to store all the micro-frames, but may be configured not to hold some data. For example, the storage capacity may be reduced by employing a method of holding only the maximum value of a plurality of sub-frames.

### Second Embodiment

In the present embodiment, a modified example in which two stages of ranging with different distance resolution are performed during one ranging frame period of the first embodiment will be described. In the present embodiment, the description of elements common to those of the first embodiment may be omitted or simplified.

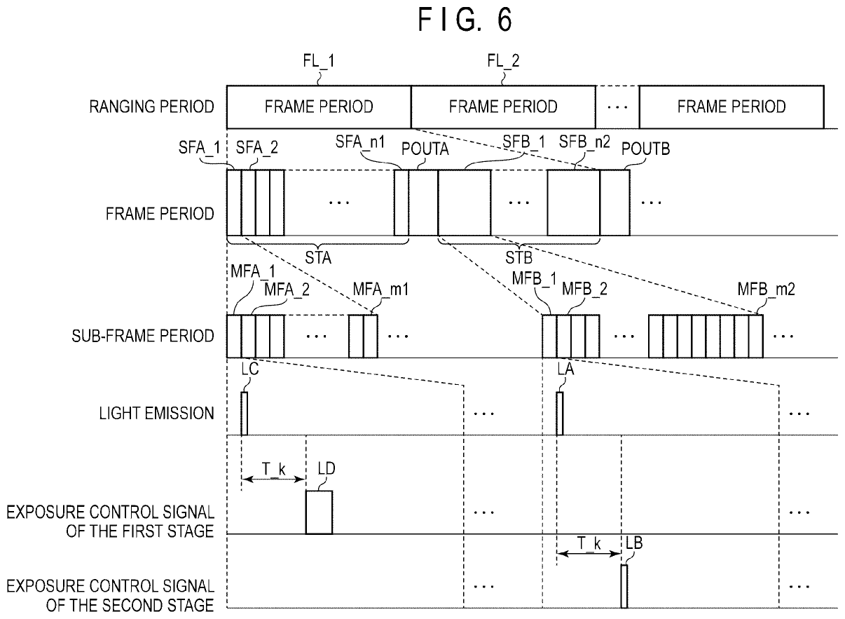

FIG. 6 is a diagram illustrating an outline of ranging frame acquisition according to the present embodiment. As illustrated in the “frame period” of FIG. 6, one ranging frame period is divided into two stages of a first stage STA and a second stage STB. In the first stage STA of the frame period, n1 sub-frames are acquired in a plurality of sub-frame periods SFA_1, SFA_2, . . . , SFA_n1, and then peak determination and output are performed in the peak output period POUTA. In the second stage STB of the frame period, n2 sub-frames are acquired in a plurality of sub-frame periods SFB_1, SFB_2, . . . , SFB_n2, and then peak determination and output are performed in the peak output period POUTB. Note that both n1 and n2 are integers of 2 or more.

The “sub-frame period” indicates a plurality of micro-frame periods MFA_1, MFA_2, . . . , MFA_m1 included in one sub-frame period of the first stage STA. In addition, the “sub-frame period” also indicates a plurality of micro-frame periods MFB_1, MFB_2, . . . , MFB_m2 included in one sub-frame period of the second stage STB. Note that m1 and m2 are both integers of 2 or more.

The binning processing is enabled in the first stage STA, and the binning processing is disabled in the second stage STB. As illustrated in the “exposure control signal of the first stage” and the “exposure control signal of the second stage” of FIG. 6, the exposure period LD of the first stage STA is longer than the exposure period LB of the second stage STB.

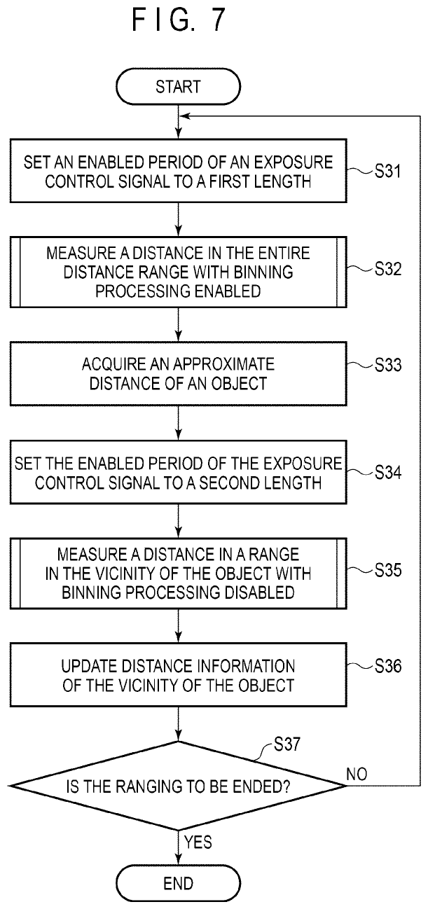

FIG. 7 is a flowchart illustrating an operation of the ranging device 1 according to the present embodiment. FIG. 7 illustrates the operation from the start to the end of the ranging period.

In step S31, the control unit 31 sets an enabled period (the high level period of the exposure period LD) of the exposure control signal for the first stage STA to a first length. The first length is longer than a second length set in step S34 described later. In other words, in the first stage STA, the ranging is performed in a state where the detection period of the reflected light is long and the resolution in the distance direction is low.

In step S32 corresponding to the first stage STA, the ranging device 1 performs the same ranging processing as in FIG. 5 in a state where the binning processing is enabled and the distance range of the ranging is set to the entire range. That is, in a state in which YES is selected in the steps S15 and S19 in FIG. 5, the same ranging processing as in FIG. 5 is performed. Therefore, as in the first embodiment, the number of micro-frames per one sub-frame is ¼ as compared with the case where the binning processing is disabled.

In step S33, the ranging device 1 acquires an approximate distance of the object X from the distance information acquired from the frequency distribution (second frequency distribution) acquired in the processing of the step S32. The acquisition range of the ranging in the second stage STB is set based on the approximate distance. By the above-described processing, the distance information in which all of the resolution in the row direction, the resolution in the column direction, and the resolution in the distance direction of the pixels P are low is acquired.

In step S34, the control unit 31 sets an enabled period (the high level period of the exposure period LB) of the exposure control signal for the second stage STB to a second length. The second length is shorter than the first length. In other words, in the second stage STB, the ranging is performed in a state where the resolution in the distance direction is higher than that in the first stage STA.

In step S35 corresponding to the second stage STB, the ranging device 1 performs the same ranging processing as that in FIG. 5 in a state in which the binning processing is disabled and the distance range of the ranging is set narrow to a predetermined range in the vicinity of the approximate distance of the object X. That is, in a state in which NO is selected in the steps S15 and S19 in FIG. 5, the same ranging processing as in FIG. 5 is performed. By the above-described processing, the distance information in which all of the resolution in the row direction, the resolution in the column direction, and the resolution in the distance direction of the pixels P are high is acquired. The predetermined range in which the ranging is performed in the second stage STB corresponds to, for example, a distance range covered by one sub-frame of the first stage STA.

In step S36, the ranging device 1 updates the distance information by replacing a portion of the distance information acquired in the step S32 in the vicinity of the approximate distance of the object X with the distance information acquired from the frequency distribution (first frequency distribution) acquired in the step S35.

In step S37, the control unit 31 determines whether or not the ranging is to be ended. When it is determined that the ranging is to be ended (YES in the step S37), the process ends. When it is determined that the ranging is not to be ended (NO in the step S37), the process proceeds to the step S31, where the next ranging frame is acquired.

According to the present embodiment, the number of micro-frames to be acquired can be reduced while maintaining the resolution in the vicinity of the object X, and the processing time can be shortened. Therefore, the photoelectric conversion device capable of, in addition to the effects similar to those of the first embodiment, improving the frame rate while maintaining the accuracy in the vicinity of the object X is provided.

Here, comparison between the number of micro-frames in a case where the ranging processing is performed without binning in the entire distance and the number of micro-frames of the present embodiment will be described. For example, as in the first embodiment, when the maximum value of the number of photons detected per one sub-frame is 63 and the distance resolution is 128, the number of micro-frames for acquiring one ranging frame is 8064. On the other hand, in the present embodiment, it is assumed that the distance resolution of the first stage STA is 8 and the distance resolution of the second stage STB is 16, and the measurement range of the second stage STB is a range covered by one sub-frame of the first stage STA. In this case, the number of micro-frames in the first stage STA is 16×8=128 micro-frames, and the number of micro-frames in the second stage STB is 63×16=1008 micro-frames. Since sum of these is 1136 micro-frames, the number of micro-frames to be acquired can be reduced while maintaining the resolution in the vicinity of the object X.

Note that in the first stage STA, the reading may not be performed for a distance range in which it is known that the object X does not exist. In this case, it is possible to further speed up the ranging processing.

### Third Embodiment

In the present embodiment, an application example of switching the presence or absence of binning processing according to the first embodiment will be described. In the present embodiment, the description of elements common to those of the first embodiment may be omitted or simplified. Although the application example described in the present embodiment is ranging processing for a vehicle for automatic driving, driving assistance, and the like, the application example is not limited thereto.

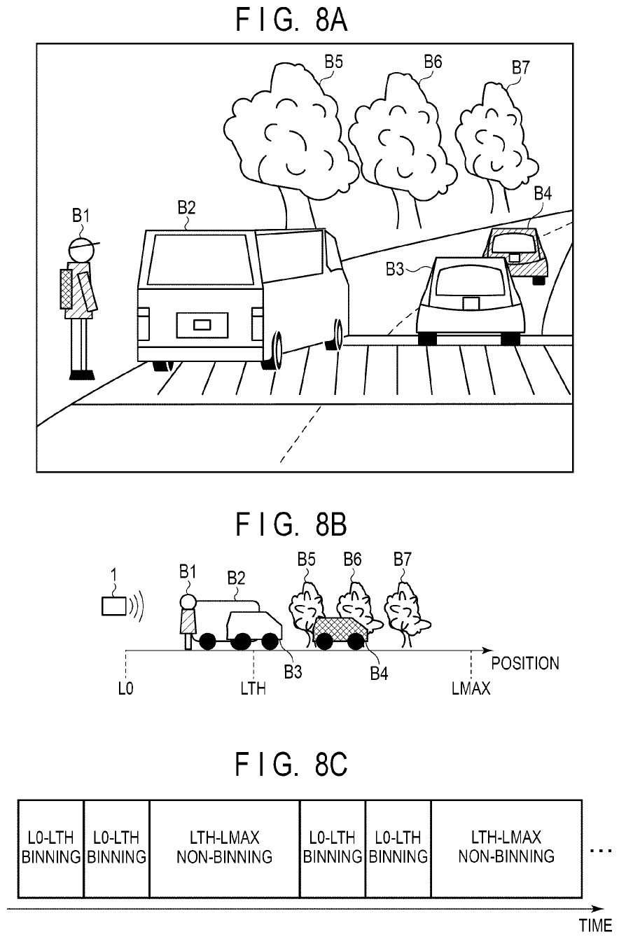

FIGS. 8A, 8B, and 8C are schematic views illustrating an outline of an operation of the ranging device 1 according to the present embodiment. FIG. 8A illustrates an example of an image outside the vehicle captured by the vehicle-mounted camera. FIG. 8A illustrates objects B1 to B7 for ranging.

FIG. 8B is a diagram schematically illustrating positions of the ranging device 1 and the objects B1 to B7 in the depth direction of FIG. 8A. It is assumed that the ranging device 1 is at a position L0. It is assumed that the objects B1 to B7 are located between the position L0 and a position LMAX. The position LMAX is a position farthest from the ranging device 1 in the ranging area. A position between the position L0 and a position LTH (the distance is less than a threshold value) is defined as a short distance, and a distance between the position LTH and the position LMAX (the distance is equal to or greater than the threshold value) is defined as a long distance. That is, the position LTH is the threshold value between the short distance and the long distance.

FIG. 8C is a diagram schematically illustrating the distance range of ranging and the presence or absence of binning processing in time series. One box in FIG. 8C indicates one ranging frame, and a description in the box indicates conditions of ranging processing. As illustrated in FIG. 8C, ranging under different conditions is repeated a plurality of times. The “L0-LTH” indicates that ranging is performed in a range of the short distance from the position L0 to the position LTH. The “LTH-LMAX” indicates that ranging is performed in a range of the long distance from the position LTH to the position LMAX. The “binning” indicates that the binning processing described in the first embodiment is enabled. The “non-binning” indicates that the binning processing described in the first embodiment is disabled. As illustrated in FIG. 8C, a setting is adopted in which the binning processing is enabled when the ranging is performed at the short distance from the position L0 to the position LTH, and the binning processing is disabled when the ranging is performed at the long distance from the position LTH to the position LMAX. Also, as illustrated in FIG. 8C, the ranging at the short distance is performed more frequently than the ranging at the long distance.

An effect of the above setting will be described. In general, the collision possibility of an object in the short distance from the own vehicle is higher than the collision possibility of an object in the long distance from the own vehicle. Therefore, in the ranging for a vehicle, it is desired to increase the frequency of the ranging at the short distance. In the examples of FIGS. 8A and 8B, the objects B1, B2, and B3 in the short distance are likely to affect the own vehicle as compared with the objects B4, B5, B6, and B7 in the long distance. Accordingly, in the present embodiment, the ranging at the short distance is performed more frequently than the ranging at the long distance. Accordingly, the object can be detected earlier by frequently performing ranging for the object in the short distance object with a high possibility of collision.

Further, generally, an object at the short distance tends to have a larger size in an image than an object at the long distance. Therefore, even if the resolution in the row direction and the column direction of the pixels P is lowered by the binning processing, the influence on the detection of the object is small. Therefore, in the present embodiment, the binning processing is enabled when the ranging is performed at the short distance, and the binning processing is disabled when the ranging is performed at the long distance. This makes it possible to perform the ranging at the short distance at high speed and at high frequency, and secures the resolution of the ranging at the long distance.

Therefore, according to the present embodiment, the same effect as in the first embodiment can be obtained, and the ranging device 1 capable of ensuring the appropriate detection frequency and resolution according to the distance can be provided.

In the case of ranging at the long distance, the length of the enabled period of the exposure control signal may be made longer than that in the case of ranging at the short distance to lower the distance resolution. Thereby, the number of micro-frames to be acquired can be reduced, and the processing time can be reduced.

FIG. 8C illustrates an example in which the ranging from the position LTH to the position LMAX is collectively performed. For example, the ranging between the position LTH and the position LMAX may be divided into a plurality of processes, and the plurality of processes may be performed in different periods between the periods for ranging at the short distance. As a result, since the period of the short-distance ranging can be made constant, the time interval of the ranging at the short distance can be shortened.

As in the first embodiment, the rate of change in the number of micro-frames depending on the presence or absence of binning processing may be 1:4, but is not limited thereto. For example, when the distance to the object is short, the reflected light of the light emitted from the light emitting unit 20 is likely to be detected by the light receiving unit 40. Therefore, the rate of change in the number of micro-frames may be smaller than ¼ and is also less susceptible to disturbance.

On the other hand, when the distance of the object is long, the reflected light of the light emitted from the light emitting unit 20 is not likely to be detected by the light receiving unit 40. Therefore, the binning processing may be enabled even in the case of ranging at the long distance, and the detection rate of reflected light can be improved. Further, for example, by utilizing the storage area of the frequency distribution for pixels that is not used by the binning processing, the number of micro-frames per one sub-frame in the ranging at the long distance may be increased, and the detection accuracy may be improved.

### Fourth Embodiment

In the first to third embodiments described above, the configuration and the control method of the ranging device 1 according to a scheme of controlling the ranging area using the exposure control signal have been described. However, the scheme applicable to the ranging device 1 is not limited thereto. As another scheme, a circuit called a time-to-digital converter (TDC) is applicable. In this method, a time counting operation is started by a counter that measures an elapsed time from light emission simultaneously with light emission, and a distance of the object is acquired from a time count value at the time of reception of a light reception pulse indicating that a pixel has received reflected light and an operating frequency of the counter. In the present embodiment, an application example of a method using the TDC will be described. In the present embodiment, description of elements common to the first to third embodiments may be omitted or simplified.

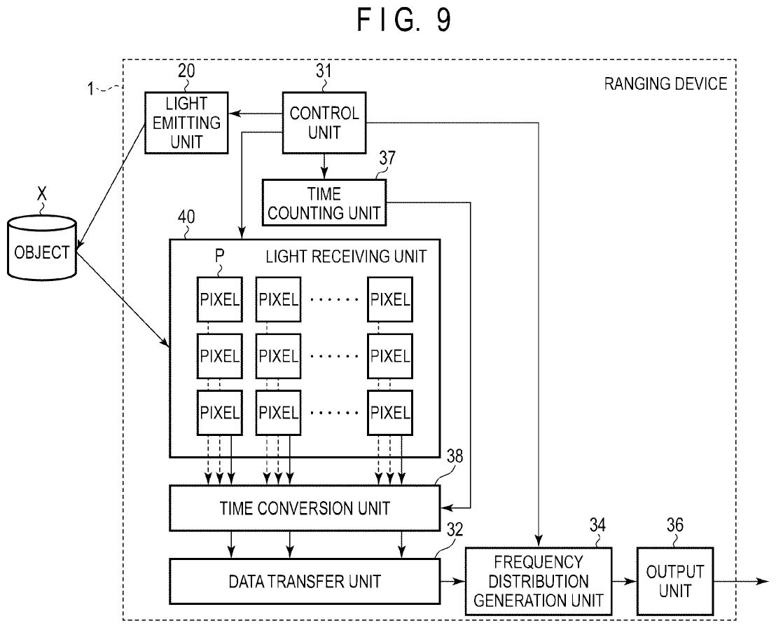

FIG. 9 is a functional block diagram illustrating a schematic configuration example of the ranging device 1 according to the present embodiment. The ranging device 1 according to the present embodiment includes a time counting unit 37 and a time conversion unit 38 instead of the binning processing unit 33 and the frequency distribution holding unit 35 in the configuration illustrated in FIG. 2.

The control unit 31 outputs a light emission control signal for controlling the timing of light emission to the light emitting unit 20. The control unit 31 outputs a control signal for controlling the operation start and the operation end of the time counting in the time counting unit 37 in synchronization with the light emission control signal. Further, the control unit 31 outputs driving pulses for driving the pixels P to the light receiving unit 40, and controls exposure of the pixels P and output of light reception pulses from the pixels P in a predetermined region. Further, the control unit 31 controls the number of measurements (the number of repetitions of light emission processing and light reception processing) in one ranging. The number of measurements is the accumulation number of light reception results for generating the frequency distribution.

The pixel P does not perform exposure control processing based on the exposure control signal illustrated in the first to third embodiments. Instead, the pixel P outputs the light reception pulse to the time conversion unit 38 at the timing of detecting a photon during the enabled period of the time counting operation of the time counting unit 37.

The time counting unit 37 may include a counter that performs time counting based on a clock signal. The time counting unit 37 starts outputting the time count value to the time conversion unit 38 when receiving the start control of the time counting operation from the control unit 31. Then, the time counting unit 37 stops outputting the time count value when the time counting unit 37 receives the end control of the time counting operation from the control unit 31.

The time conversion unit 38 includes the above-described TDC. The time conversion unit 38 refers to the time count value output from the time counting unit 37, and outputs, to the data transfer unit 32, the time count value at the time when the light reception pulse output from each pixel P is received. The data transfer unit 32 outputs a time count value indicating the light reception timing of the pixel P as many as a predetermined number of pixels in one cycle. Since the time count value indicates the flight time of light from light emission to light reception, the time count value corresponds to the distance from the ranging device 1 to the object X.

The frequency distribution generation unit 34 generates a frequency distribution in which the time (or distance) is defined as the class and the number of times of light reception is defined as the frequency, based on the control signal output from the control unit 31 and the time count value output from the data transfer unit 32. When the control signal output from the control unit 31 instructs disabling of the binning processing, the frequency distribution generation unit 34 generates a frequency distribution for each of the plurality of pixels P. On the other hand, when the control signal output from the control unit 31 instructs enabling of the binning processing, the frequency distribution generation unit 34 generates a frequency distribution in which time count values corresponding to output signals of a plurality of pixels P to be binned are integrated into one.

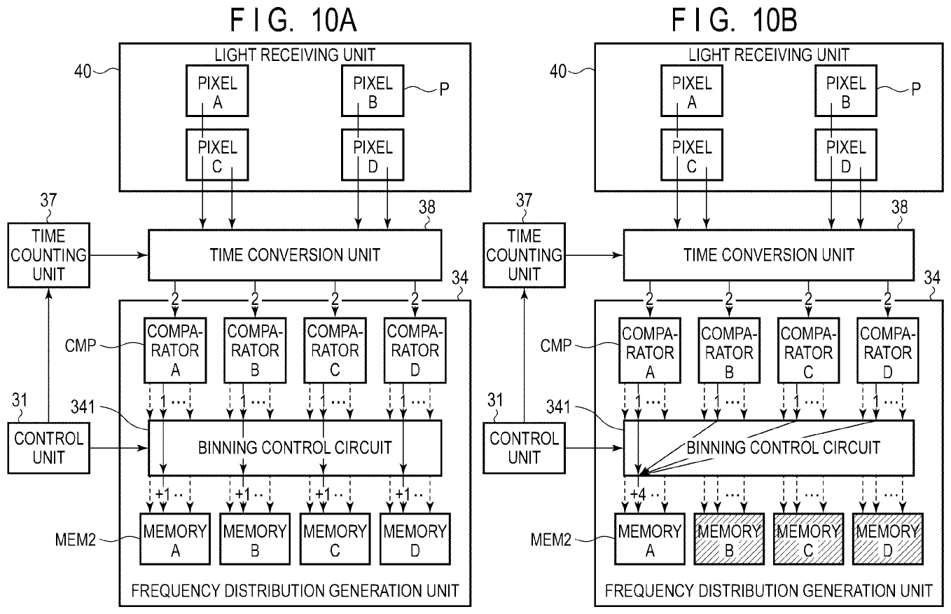

FIGS. 10A and 10B are block diagrams schematically illustrating binning processing according to the present embodiment. FIGS. 10A and 10B illustrate in more detail the elements related to the binning processing among the light receiving unit 40, the control unit 31, the time counting unit 37, the time conversion unit 38, and the frequency distribution generation unit 34. FIG. 10A illustrates the operation when the binning processing is disabled, and FIG. 10B illustrates the operation when the binning processing is enabled. As illustrated in FIGS. 10A and 10B, in the binning processing in the present embodiment, binning processing is performed on four adjacent pixels P of two rows and two columns, but the number of pixels P to be binned is not limited thereto. Since the data transfer unit 32 is unnecessary in the description of the binning processing, the data transfer unit 32 is omitted in FIGS. 10A and 10B.

In FIGS. 10A and 10B, the four pixels P are labeled with “pixel A”, “pixel B”, “pixel C”, and “pixel D” in order to distinguish them from each other. The frequency distribution generation unit 34 includes four comparators CMP, four memories MEM2, and a binning control circuit 341. The four comparators CMP are labeled with “comparator A”, “comparator B”, “comparator C”, and “comparator D” in order to distinguish them. The “comparator A”, the “comparator B”, the “comparator C”, and the “comparator D” are arranged corresponding to the “pixel A”, the “pixel B”, the “pixel C”, and the “pixel D”, respectively. The four memories MEM2 are labeled with “memory A”, “memory B”, “memory C”, and “memory D” in order to distinguish them from each other. The “memory A”, the “memory B”, the “memory C”, and the “memory D” are arranged corresponding to the “pixel A”, the “pixel B”, the “pixel C”, and the “pixel D”, respectively.

As described with reference to FIG. 9, the time conversion unit 38 outputs, to the frequency distribution generation unit 34, the time count value at the time of receiving the light reception pulse output from the pixel P for each of the plurality of pixels P. In the examples of FIGS. 10A and 10B, it is assumed that the time conversion unit 38 outputs “2” for all four pixels P.

The comparator CMP converts the time count value that is input into one-hot digital data and outputs the one-hot digital data to the binning control circuit 341. Since “2” is input to the comparator CMP in this example, the comparator CMP outputs digital data in which the second digit is “1” and the other digits are “0”. The one-hot digital data is information indicating an addition value to each digit of the memory MEM2.

The binning control circuit 341 can switch between enabling and disabling of the binning processing in accordance with the control signal output from the control unit 31. The binning control circuit 341 can perform processing of adding a predetermined value to each digit of the digital data stored in the four memories.

As illustrated in FIG. 10A, when the binning processing is disabled, the binning control circuit 341 adds a value of the one-hot digital data to the memory MEM2 corresponding to each pixel P. In the example of FIG. 10A, the value of the second digit of each memory MEM2 is added by 1. By repeating this operation, the frequency distribution of the corresponding pixel P is generated in each memory MEM2.

As illustrated in FIG. 10B, when the binning processing is enabled, the binning control circuit 341 performs processing of adding a sum of values of four one-hot digital data to one memory MEM2 (the memory A in FIG. 10B). In the example of FIG. 10A, the value of the second digit of one memory MEM2 is added by four. By repeating this operation, a frequency distribution in which outputs of four pixels P are accumulated in one memory MEM2 is generated. In FIG. 10B, the memory MEM2 illustrated by the hatched box indicates the memory MEM2 that does not perform the storage operation of the frequency distribution. For the memory MEM2 that does not perform the storage operation, it is preferable to perform power saving processing by a method such as stopping or reducing the supply of power. Thereby, the power consumption of the memory MEM2 when the binning processing is enabled can be made smaller than the power consumption of the memory MEM2 when the binning processing is disabled.

When the object X at the same distance is detected by the four pixels P, the frequency distribution is generated at a speed four times higher than that in the case where the binning processing is disabled by performing the binning processing. Therefore, although the resolutions in the row direction and the column direction of the pixels P are reduced by performing the binning processing, the frequency distribution can be generated by approximately ¼ of the number of measurements compared to the case where the binning processing is disabled.

As described above, even in the configuration of the present embodiment using the TDC, the number of measurements can be reduced and the processing time can be shortened in the case where the binning processing is enabled, as in the first to third embodiments. Accordingly, a photoelectric conversion device capable of improving a frame rate is provided.

In the present embodiment, the binning processing for the output signal of each pixel P is performed before the generation of the frequency distribution, but the timing of the binning processing is not limited to thereto. For example, the frequency distribution of each pixel P may be generated individually, and a plurality of frequency distributions may be summed when the distance is calculated. Also in this case, by making the number of measurements when the binning processing is enabled smaller than the number of measurements when the binning processing is disabled, the processing time can be shortened.

### Fifth Embodiment

In the present embodiment, a specific configuration example of a photoelectric conversion device that includes an avalanche photodiode and that can be applied to the ranging device 1 according to the first to fourth embodiments will be described. The configuration example of the present embodiment is an example, and the photoelectric conversion device applicable to the ranging device 1 is not limited thereto.

FIG. 11 is a schematic diagram illustrating an overall configuration of the photoelectric conversion device 100 according to the present embodiment. The photoelectric conversion device 100 includes a sensor substrate 11 (first substrate) and a circuit substrate 21 (second substrate) stacked on each other. The sensor substrate 11 and the circuit substrate 21 are electrically connected to each other. The sensor substrate 11 has a pixel region 12 in which a plurality of pixels 101 are arranged to form a plurality of rows and a plurality of columns. The circuit substrate 21 includes a first circuit region 22 in which a plurality of pixel signal processing units 103 are arranged to form a plurality of rows and a plurality of columns, and a second circuit region 23 arranged outside the first circuit region 22. The second circuit region 23 may include a circuit for controlling the plurality of pixel signal processing units 103. The sensor substrate 11 has a light incident surface for receiving incident light and a connection surface opposed to the light incident surface. The sensor substrate 11 is connected to the circuit substrate 21 on the connection surface side. That is, the photoelectric conversion device 100 is a so-called backside illumination type.

In this specification, the term “plan view” refers to a view from a direction perpendicular to a surface opposite to the light incident surface. The cross section indicates a surface in a direction perpendicular to a surface opposite to the light incident surface of the sensor substrate 11. Although the light incident surface may be a rough surface when viewed microscopically, in this case, a plan view is defined with reference to the light incident surface when viewed macroscopically.

In the following description, the sensor substrate 11 and the circuit substrate 21 are diced chips, but the sensor substrate 11 and the circuit substrate 21 are not limited to chips. For example, the sensor substrate 11 and the circuit substrate 21 may be wafers. When the sensor substrate 11 and the circuit substrate 21 are diced chips, the photoelectric conversion device 100 may be manufactured by being diced after being stacked in a wafer state, or may be manufactured by being stacked after being diced.

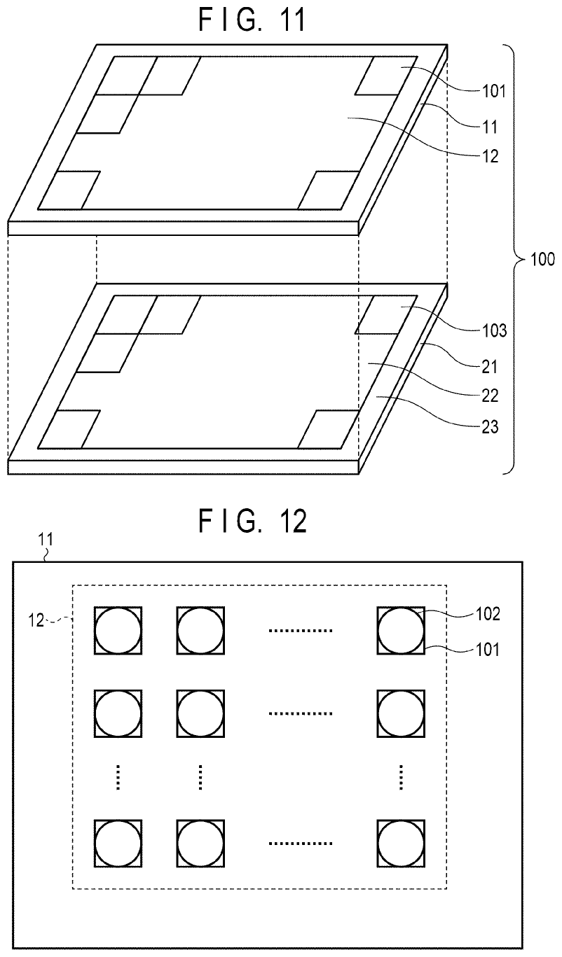

FIG. 12 is a schematic block diagram illustrating an arrangement example of the sensor substrate 11. In the pixel region 12, a plurality of pixels 101 are arranged to form a plurality of rows and a plurality of columns. Each of the plurality of pixels 101 includes a photoelectric conversion unit 102 including an avalanche photodiode (hereinafter referred to as APD) as a photoelectric conversion element in the substrate.

Of the charge pairs generated in the APD, the conductivity type of the charge used as the signal charge is referred to as a first conductivity type. The first conductivity type refers to a conductivity type in which a charge having the same polarity as the signal charge is a majority carrier. Further, a conductivity type opposite to the first conductivity type, that is, a conductivity type in which a majority carrier is a charge having a polarity different from that of a signal charge is referred to as a second conductivity type. In the APD described below, the anode of the APD is set to a fixed potential, and a signal is extracted from the cathode of the APD. Accordingly, the semiconductor region of the first conductivity type is an N-type semiconductor region, and the semiconductor region of the second conductivity type is a P-type semiconductor region. Note that the cathode of the APD may have a fixed potential and a signal may be extracted from the anode of the APD. In this case, the semiconductor region of the first conductivity type is the P-type semiconductor region, and the semiconductor region of the second conductivity type is then N-type semiconductor region. Although the case where one node of the APD is set to a fixed potential is described below, potentials of both nodes may be varied.

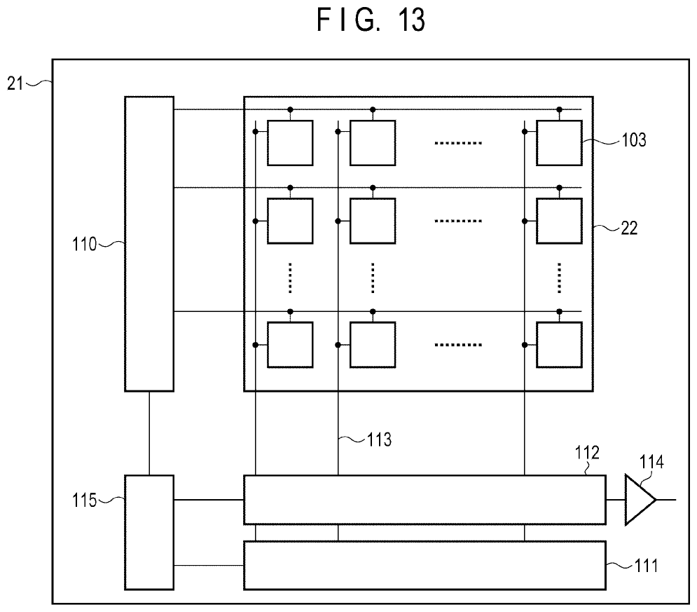

FIG. 13 is a schematic block diagram illustrating a configuration example of the circuit substrate 21. The circuit substrate 21 has the first circuit region 22 in which a plurality of pixel signal processing units 103 are arranged to form a plurality of rows and a plurality of columns.

The circuit substrate 21 includes a vertical scanning circuit 110, a horizontal scanning circuit 111, a reading circuit 112, a pixel output signal line 113, an output circuit 114, and a control signal generation unit 115. The plurality of photoelectric conversion units 102 illustrated in FIG. 12 and the plurality of pixel signal processing units 103 illustrated in FIG. 13 are electrically connected to each other via connection wirings provided for each pixels 101.

The control signal generation unit 115 is a control circuit that generates control signals for driving the vertical scanning circuit 110, the horizontal scanning circuit 111, and the reading circuit 112, and supplies the control signals to these units. As a result, the control signal generation unit 115 controls the driving timings and the like of each unit.

The vertical scanning circuit 110 supplies control signals to each of the plurality of pixel signal processing units 103 based on the control signal supplied from the control signal generation unit 115. The vertical scanning circuit 110 supplies control signals for each row to the pixel signal processing unit 103 via a driving line provided for each row of the first circuit region 22. As will be described later, a plurality of driving lines may be provided for each row. A logic circuit such as a shift register or an address decoder can be used for the vertical scanning circuit 110. Thus, the vertical scanning circuit 110 selects a row to be output a signal from the pixel signal processing unit 103.

The signal output from the photoelectric conversion unit 102 of the pixel 101 is processed by the pixel signal processing unit 103. The pixel signal processing unit 103 counts pulses output from the APD included in the photoelectric conversion unit 102 to acquire and hold a digital signal.

It is not always necessary to provide one pixel signal processing unit 103 for each of the pixels 101. For example, one pixel signal processing unit 103 may be shared by a plurality of pixels 101. In this case, the pixel signal processing unit 103 sequentially processes the signals output from the photoelectric conversion units 102, thereby providing the function of signal processing to each pixel 101.

The horizontal scanning circuit 111 supplies control signals to the reading circuit 112 based on a control signal supplied from the control signal generation unit 115. The pixel signal processing unit 103 is connected to the reading circuit 112 via a pixel output signal line 113 provided for each column of the first circuit region 22. The pixel output signal line 113 in one column is shared by a plurality of pixel signal processing units 103 in the corresponding column. The pixel output signal line 113 includes a plurality of wirings, and has at least a function of outputting a digital signal from the pixel signal processing unit 103 to the reading circuit 112, and a function of supplying a control signal for selecting a column for outputting a signal to the pixel signal processing unit 103. The reading circuit 112 outputs a signal to an external storage unit or signal processing unit of the photoelectric conversion device 100 via the output circuit 114 based on the control signal supplied from the control signal generation unit 115.

The arrangement of the photoelectric conversion units 102 in the pixel region 12 may be one-dimensional. Further, the function of the pixel signal processing unit 103 does not necessarily have to be provided one by one in all the pixels 101. For example, one pixel signal processing unit 103 may be shared by a plurality of pixels 101. In this case, the pixel signal processing unit 103 sequentially processes the signals output from the photoelectric conversion units 102, thereby providing the function of signal processing to each pixel 101.

As illustrated in FIGS. 12 and 13, the first circuit region 22 having a plurality of pixel signal processing units 103 is arranged in a region overlapping the pixel region 12 in the plan view. In the plan view, the vertical scanning circuit 110, the horizontal scanning circuit 111, the reading circuit 112, the output circuit 114, and the control signal generation unit 115 are arranged so as to overlap a region between an edge of the sensor substrate 11 and an edge of the pixel region 12. In other words, the sensor substrate 11 includes the pixel region 12 and a non-pixel region arranged around the pixel region 12. In the circuit substrate 21, the second circuit region 23 (described above in FIG. 11) having the vertical scanning circuit 110, the horizontal scanning circuit 111, the reading circuit 112, the output circuit 114, and the control signal generation unit 115 is arranged in a region overlapping with the non-pixel region in the plan view.

Note that the arrangement of the pixel output signal line 113, the arrangement of the reading circuit 112, and the arrangement of the output circuit 114 are not limited to those illustrated in FIG. 13. For example, the pixel output signal lines 113 may extend in the row direction, and may be shared by a plurality of pixel signal processing units 103 in corresponding rows. The reading circuit 112 may be provided so as to be connected to the pixel output signal line 113 of each row.

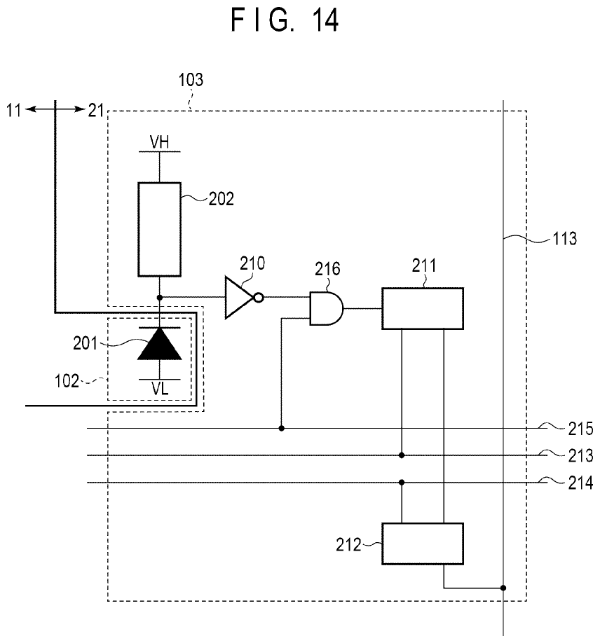

FIG. 14 is a schematic block diagram illustrating a configuration example of one pixel of the photoelectric conversion unit 102 and the pixel signal processing unit 103 according to the present embodiment. FIG. 14 schematically illustrates a more specific configuration example including a connection relationship between the photoelectric conversion unit 102 arranged in the sensor substrate 11 and the pixel signal processing unit 103 arranged in the circuit substrate 21. In FIG. 14, driving lines between the vertical scanning circuit 110 and the pixel signal processing unit 103 in FIG. 13 are illustrated as driving lines 213, 214, and 215.

The photoelectric conversion unit 102 includes an APD 201. The pixel signal processing unit 103 includes a quenching element 202, a waveform shaping unit 210, a counter circuit 211, a selection circuit 212, and a gating circuit 216. The pixel signal processing unit 103 may include at least one of the waveform shaping unit 210, the counter circuit 211, the selection circuit 212, and the gating circuit 216.

The APD 201 generates a charge corresponding to incident light by photoelectric conversion. A voltage VL (first voltage) is supplied to the anode of the APD 201. The cathode of the APD 201 is connected to a first terminal of the quenching element 202 and an input terminal of the waveform shaping unit 210. A voltage VH (second voltage) higher than the voltage VL supplied to the anode is supplied to the cathode of the APD 201. As a result, a reverse bias voltage that causes the APD 201 to perform the avalanche multiplication operation is supplied to the anode and the cathode of the APD 201. In the APD 201 to which the reverse bias voltage is supplied, when a charge is generated by the incident light, this charge causes avalanche multiplication, and an avalanche current is generated.

The operation modes in the case where a reverse bias voltage is supplied to the APD 201 include a Geiger mode and a linear mode. The Geiger mode is a mode in which a potential difference between the anode and the cathode is higher than a breakdown voltage, and the linear mode is a mode in which a potential difference between the anode and the cathode is near or lower than the breakdown voltage.

The APD operated in the Geiger mode is referred to as a single photon avalanche diode (SPAD). In this case, for example, the voltage VL (first voltage) is −30 V, and the voltage VH (second voltage) is 1 V. The APD 201 may operate in the linear mode or the Geiger mode. In the case of the SPAD, a potential difference becomes greater than that of the APD of the linear mode, and the effect of avalanche multiplication becomes significant, so that the SPAD is preferable.

The quenching element 202 functions as a load circuit (quenching circuit) when a signal is multiplied by avalanche multiplication. The quenching element 202 suppresses the voltage supplied to the APD 201 and suppresses the avalanche multiplication (quenching operation). Further, the quenching element 202 returns the voltage supplied to the APD 201 to the voltage VH by passing a current corresponding to the voltage drop due to the quenching operation (recharge operation). The quenching element 202 may be, for example, a resistive element.

The waveform shaping unit 210 shapes the potential change of the cathode of the APD 201 obtained at the time of photon detection, and outputs a pulse signal. For example, an inverter circuit is used as the waveform shaping unit 210. Although FIG. 14 illustrates an example in which one inverter is used as the waveform shaping unit 210, the waveform shaping unit 210 may be a circuit in which a plurality of inverters are connected in series, or may be another circuit having a waveform shaping effect.

The gating circuit 216 performs gating such that the pulse signal output from the waveform shaping unit 210 passes through for a predetermined period. During a period in which the pulse signal can pass through the gating circuit 216, a photon incident on the APD 201 is counted by the counter circuit 211 in the subsequent stage. Accordingly, the gating circuit 216 controls an exposure period during which a signal based on incident light is generated in the pixel 101. The period during which the pulse signal passes is controlled by a control signal supplied from the vertical scanning circuit 110 through the driving line 215. FIG. 14 illustrates an example in which one AND circuit is used as the gating circuit 216. The pulse signal and the control signal are input to two input terminals of the AND circuit. The AND circuit outputs logical conjunction of these to the counter circuit 211. Note that, the gating circuit 216 may have a circuit configuration other than the AND circuit as long as it realizes gating. Also, the waveform shaping unit 210 and the gating circuit 216 may be integrated by using a logic circuit such as a NAND circuit.

The counter circuit 211 counts the pulse signals output from the waveform shaping unit 210 via the gating circuit 216, and holds a digital signal indicating the count value. When a control signal is supplied from the vertical scanning circuit 110 through the driving line 213, the counter circuit 211 resets the held signal. The counter circuit 211 may be, for example, a one-bit counter.

The selection circuit 212 is supplied with a control signal from the vertical scanning circuit 110 illustrated in FIG. 13 through the driving line 214 illustrated in FIG. 14. In response to this control signal, the selection circuit 212 switches between the electrical connection and the non-connection of the counter circuit 211 and the pixel output signal line 113. The selection circuit 212 includes, for example, a buffer circuit or the like for outputting a signal corresponding to a value held in the counter circuit 211.

In the example of FIG. 14, the selection circuit 212 switches between the electrical connection and the non-connection of the counter circuit 211 and the pixel output signal line 113; however, the method of controlling the signal output to the pixel output signal line 113 is not limited thereto. For example, a switch such as a transistor may be arranged at a node such as between the quenching element 202 and the APD 201 or between the photoelectric conversion unit 102 and the pixel signal processing unit 103, and the signal output to the pixel output signal line 113 may be controlled by switching the electrical connection and the non-connection. Alternatively, the signal output to the pixel output signal line 113 may be controlled by changing the value of the voltage VH or the voltage VL supplied to the photoelectric conversion unit 102 using a switch such as a transistor.

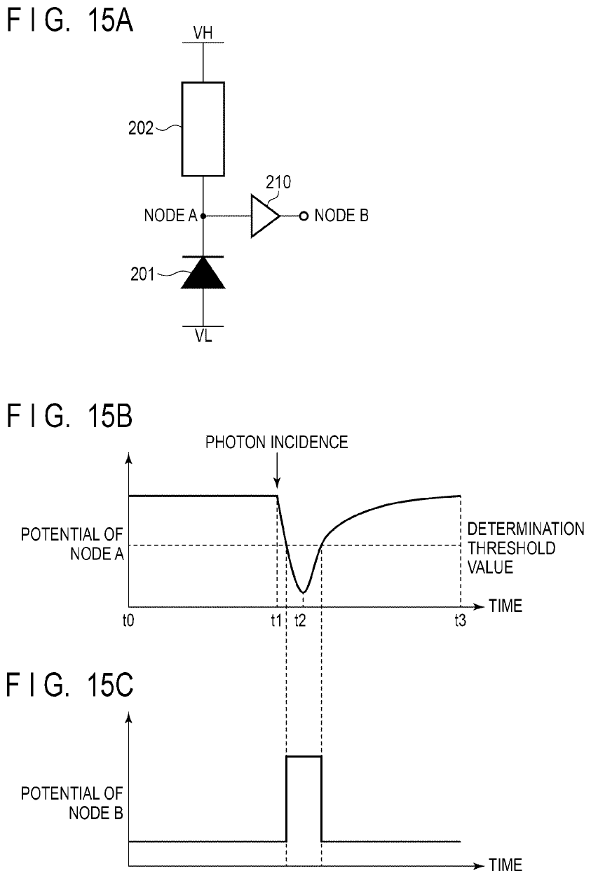

FIGS. 15A, 15B, and 15C are diagrams illustrating an operation of the APD 201 according to the present embodiment. FIG. 15A is a diagram illustrating the APD 201, the quenching element 202, and the waveform shaping unit 210 in FIG. 14. As illustrated in FIG. 15A, the connection node of the APD 201, the quenching element 202, and the input terminal of the waveform shaping unit 210 is referred to as node A. Further, as illustrated in FIG. 15A, an output side of the waveform shaping unit 210 is referred to as node B.

FIG. 15B is a graph illustrating a temporal change in the potential of node A in FIG. 15A. FIG. 15C is a graph illustrating a temporal change in the potential of node B in FIG. 15A. During a period from time t0 to time t1, the voltage VH-VL is applied to the APD 201 in FIG. 15A. When a photon enters the APD 201 at the time t1, avalanche multiplication occurs in the APD 201. As a result, an avalanche current flows through the quenching element 202, and the potential of the node A drops. Thereafter, the amount of potential drop further increases, and the voltage applied to the APD 201 gradually decreases. Then, at time t2, the avalanche multiplication in the APD 201 stops. Thereby, the voltage level of node A does not drop below a certain constant value. Then, during a period from the time t2 to time t3, a current that compensates for the voltage drop flows from the node of the voltage VH to the node A, and the node A is settled to the original potential at the time t3.

In the above-described process, the potential of node B becomes the high level in a period in which the potential of node A is lower than a certain threshold value. In this way, the waveform of the drop of the potential of the node A caused by the incidence of the photon is shaped by the waveform shaping unit 210 and output as a pulse to the node B.

According to the present embodiment, a photoelectric conversion device using an avalanche photodiode which can be applied to the ranging device 1 of the first or second embodiment is provided.

### Sixth Embodiment

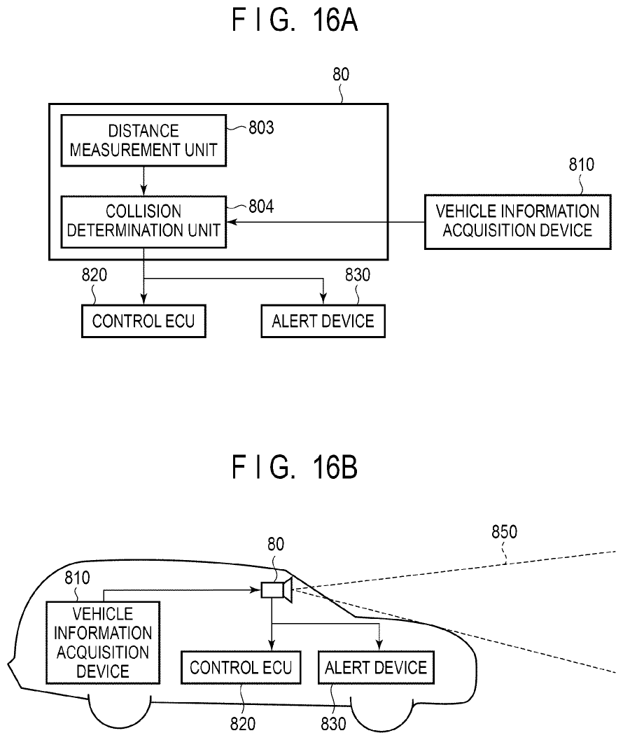

FIGS. 16A and 16B are block diagrams of equipment relating to an in-vehicle ranging device according to the present embodiment. Equipment 80 includes a distance measurement unit 803, which is an example of the ranging device 1 of the above-described embodiments, and a signal processing device (processing device) that processes a signal from the distance measurement unit 803. The equipment 80 includes the distance measurement unit 803 that measures a distance to an object, and a collision determination unit 804 that determines whether or not there is a possibility of collision based on the measured distance. The distance measurement unit 803 is an example of a distance information acquisition unit that obtains distance information to the object. That is, the distance information is information on a distance to the object or the like. The collision determination unit 804 may determine the collision possibility using the distance information.

The equipment 80 is connected to a vehicle information acquisition device 810, and can obtain vehicle information such as a vehicle speed, a yaw rate, and a steering angle. Further, the equipment 80 is connected to a control ECU 820 which is a control device that outputs a control signal for generating a braking force to the vehicle based on the determination result of the collision determination unit 804. The equipment 80 is also connected to an alert device 830 that issues an alert to the driver based on the determination result of the collision determination unit 804. For example, when the collision possibility is high as the determination result of the collision determination unit 804, the control ECU 820 performs vehicle control to avoid collision or reduce damage by braking, returning an accelerator, suppressing engine output, or the like. The alert device 830 alerts the user by sounding an alarm, displaying alert information on a screen of a car navigation system or the like, or giving vibration to a seat belt or a steering wheel. These devices of the equipment 80 function as a movable body control unit that controls the operation of controlling the vehicle as described above.

In the present embodiment, ranging is performed in an area around the vehicle, for example, a front area or a rear area, by the equipment 80. FIG. 16B illustrates equipment when ranging is performed in the front area of the vehicle (ranging area 850). The vehicle information acquisition device 810 as a ranging control unit sends an instruction to the equipment 80 or the distance measurement unit 803 to perform the ranging operation. With such a configuration, the accuracy of distance measurement can be further improved.

Although the example of control for avoiding a collision to another vehicle has been described above, the embodiment is applicable to automatic driving control for following another vehicle, automatic driving control for not going out of a traffic lane, or the like. Furthermore, the equipment is not limited to a vehicle such as an automobile and can be applied to a movable body (movable apparatus) such as a ship, an airplane, a satellite, an industrial robot and a consumer use robot, or the like, for example. In addition, the equipment can be widely applied to equipment which utilizes object recognition or biometric authentication, such as an intelligent transportation system (ITS), a surveillance system, or the like without being limited to movable bodies.

### Modified Embodiments

The present invention is not limited to the above embodiments, and various modifications are possible. For example, an example in which some of the configurations of any one of the embodiments are added to other embodiments and an example in which some of the configurations of any one of the embodiments are replaced with some of the configurations of other embodiments are also embodiments of the present invention.

The disclosure of this specification includes a complementary set of the concepts described in this specification. That is, for example, if a description of “A is B” (A=B) is provided in this specification, this specification is intended to disclose or suggest that “A is not B” even if a description of “A is not B” (A≠B) is omitted. This is because it is assumed that “A is not B” is considered when “A is B” is described.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

It should be noted that any of the embodiments described above is merely an example of an embodiment for carrying out the present invention, and the technical scope of the present invention should not be construed as being limited by the embodiments. That is, the present invention can be implemented in various forms without departing from the technical idea or the main features thereof.

According to the present invention, a photoelectric conversion device capable of improving a frame rate is provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-005962, filed Jan. 18, 2023, which is hereby incorporated by reference herein in its entirety.

What is claimed is:

1. A photoelectric conversion device comprising:
a light receiving unit including a plurality of pixels each configured to generate a signal based on incident light; and
a frequency distribution generation unit configured to generate a frequency distribution in which time information on a time from light emission of a light emitting device to light reception of the light receiving unit is associated with a frequency of light reception by accumulating light reception results at the light receiving unit a plurality of times,
wherein the frequency distribution generation unit operates in either a first mode for generating the frequency distribution from the light reception results of one of the plurality of pixels, or a second mode for generating the frequency distribution in which the light reception results of multiple pixels among the plurality of pixels are accumulated, and
wherein a second accumulation number of the light reception results in the second mode is less than a first accumulation number of the light reception results in the first mode.

2. The photoelectric conversion device according to claim 1,
wherein each of the plurality of pixels outputs a signal indicating light reception when an elapsed time from light emission of the light emitting device to light incidence is in an exposure period, and
wherein the frequency distribution is generated from the frequency of the light reception in each of a plurality of exposure periods different from each other.

3. The photoelectric conversion device according to claim 2, wherein a length of the exposure period in the second mode is longer than a length of the exposure period in the first mode.

4. The photoelectric conversion device according to claim 1 further comprising a time conversion unit configured to acquire a time count value indicating an elapsed time from light emission of the light emitting device to light reception of the light receiving unit as the time information,
wherein the frequency distribution generation unit generates the frequency distribution by accumulating the frequency of the light reception for each of a plurality of classes according to the time count value.

5. The photoelectric conversion device according to claim 1, wherein the frequency distribution generation unit sets an acquisition range of a first frequency distribution generated in the first mode based on distance information acquired from a second frequency distribution generated in the second mode.

6. The photoelectric conversion device according to claim 5, wherein the acquisition range of the first frequency distribution is narrower than the acquisition range of the second frequency distribution.

7. The photoelectric conversion device according to claim 5, wherein a distance resolution of the distance information acquired from the first frequency distribution is higher than a distance resolution of the distance information acquired from the second frequency distribution.

8. The photoelectric conversion device according to claim 1, wherein the frequency distribution generation unit switches between the first mode and the second mode according to a distance range in which ranging is performed.

9. The photoelectric conversion device according to claim 8, wherein the frequency distribution generation unit operates in the second mode when ranging is performed at a distance less than a predetermined threshold value, and operates in the first mode when ranging is performed at a distance equal to or greater than the threshold value.

10. The photoelectric conversion device according to claim 8,
wherein the frequency distribution generation unit repeats operations in the first mode or the second mode a plurality of times, and
wherein a frequency at which the frequency distribution generation unit operates in the second mode is greater than a frequency at which the frequency distribution generation unit operates in the first mode.

11. The photoelectric conversion device according to claim 10, wherein the frequency distribution generation unit performs an operation in the second mode at a constant period.

12. The photoelectric conversion device according to claim 1, wherein a ratio of the second accumulation number to the first accumulation number is less than one and equal to or greater than an inverse of the number of pixels accumulated in the second mode.

13. The photoelectric conversion device according to claim 1, wherein a ratio of the second accumulation number to the first accumulation number is less than an inverse of the number of pixels accumulated in the second mode.

14. The photoelectric conversion device according to claim 1, wherein a ratio of the second accumulation number to the first accumulation number is dynamically changed.

15. The photoelectric conversion device according to claim 1, wherein a ratio of the second accumulation number to the first accumulation number is equal to an inverse of the number of pixels accumulated in the second mode.

16. The photoelectric conversion device according to claim 1, wherein each of the plurality of pixels includes an avalanche photodiode.

17. The photoelectric conversion device according to claim 1, wherein in the second mode, at least two of the pixels in which the light reception results are accumulated are adjacent to each other.

18. The photoelectric conversion device according to claim 1, wherein power consumption of a memory that stores the frequency distribution in the second mode is less than power consumption of the memory in the first mode.

19. The photoelectric conversion device according to claim 1 further comprising an output unit configured to output distance information based on the frequency distribution.

20. A movable body comprising:
the photoelectric conversion device according to claim 1; and
a movable body control unit configured to control the movable body based on distance information acquired by the photoelectric conversion device.
